(19) United States
(12) Patent Application Publication
(10) Pub. No.: US 2026/0075716 A1
(43) Pub. Date: Mar. 12, 2026

(54) SUBSTRATE STRUCTURE

(71) Applicant: Unimicron Technology Corp., Taoyuan City (TW)

(72) Inventors: Chin-Sheng Wang, Taoyuan City (TW); Ra-Min Tain, Hsinchu County (TW); Chih-Kai Chan, Taoyuan City (TW); Chia-Fu Hsu, Taichung City (TW)

(73) Assignee: Unimicron Technology Corp., Taoyuan City (TW)

(21) Appl. No.: 19/392,163

(22) Filed: Nov. 18, 2025

Related U.S. Application Data
(63) Continuation-in-part of application No. 19/380,920, filed on Nov. 5, 2025.
Application No. 19/380,920 is a continuation-in-part of application No. 19/309,529, filed on Aug. 25, 2025.
Application No. 19/309,529 is a continuation-in-part of application No. 19/023,397, filed on Jan. 16, 2025.
Application No. 19/023,397 is a continuation-in-part of application No. 18/677,924, filed on May 30, 2024.
(60) Provisional application No. 63/623,823, filed on Jan. 23, 2024.
(60) Provisional application No. 63/666,227, filed on Jun. 30, 2024.
(60) Provisional application No. 63/699,160, filed on Sep. 26, 2024.
(60) Provisional application No. 63/836,407, filed on Jul. 1, 2025.
(60) Provisional application No. 63/850,574, filed on Jul. 25, 2025.

(30) Foreign Application Priority Data
Apr. 30, 2024 (TW) 113116076
Nov. 14, 2024 (TW) 113143769
Aug. 11, 2025 (TW) 114130495
Oct. 13, 2025 (TW) 114139209
Oct. 13, 2025 (TW) 114139210

(51) Int. Cl. H05K 1/14; H05K 1/11; H05K 3/36

(52) U.S. Cl. CPC H05K 1/144; H05K 1/113; H05K 3/368; H05K 2201/0129; H05K 2201/032; H05K 2201/041; H05K 2201/096

(57) ABSTRACT

A substrate structure includes a first substrate and a second substrate. The first substrate includes a first dielectric substrate, at least one first conductive via, at least one first conductive pad, a first bonding layer, and a first electroless metal layer. The second substrate includes a second dielectric substrate, at least one second conductive via, at least one second conductive pad a second bonding layer, and a second electroless metal layer. The second substrate is bonded to the first substrate, wherein the second bonding layer is bonded to the first bonding layer to define a non-metallic contact interface, and the second electroless metal layer is bonded to the first electroless metal layer to define a metal bonding contact interface.

### CROSS-REFERENCE TO RELATED APPLICATION

This application is a continuation-in-part application of and claims the priority benefit of a prior application U.S. application Ser. No. 19/380,920, filed on Nov. 5, 2025, now pending. This application also claims the priority benefit of U.S. provisional application Ser. No. 63/850,574, filed on Jul. 25, 2025, and Taiwan application serial no. 114139210, filed on Oct. 13, 2025. The prior U.S. application Ser. No. 19/380,920 is a continuation-in-part application of and claims the priority benefit of a prior application U.S. application Ser. No. 19/309,529, filed on Aug. 25, 2025, now pending. The prior U.S. application Ser. No. 19/380,920 also claims the priority benefit of U.S. provisional application Ser. No. 63/836,407, filed on Jul. 1, 2025, and Taiwan application serial no. 114139209, filed on Oct. 13, 2025. The prior U.S. application Ser. No. 19/309,529 is a continuation-in-part application of and claims the priority benefit of a prior application U.S. application Ser. No. 19/023,397, filed on Jan. 16, 2025, now pending. The prior U.S. application Ser. No. 19/309,529 also claims the priority benefit of U.S. provisional application Ser. No. 63/699,160, filed on Sep. 26, 2024, and Taiwan application serial no. 114130495, filed on Aug. 11, 2025. The prior U.S. application Ser. No. 19/023,397 is a continuation-in-part application of and claims the priority benefit of U.S. application Ser. No. 18/677,924, filed on May 30, 2024, now pending. The prior U.S. application Ser. No. 19/023,397 also claims the priority benefit of U.S. provisional application Ser. No. 63/666,227, filed on Jun. 30, 2024, and Taiwan application serial no. 113143769, filed on Nov. 14, 2024. The prior U.S. application Ser. No. 18/677,924 also claims the priority benefit of U.S. provisional application Ser. No. 63/623,823, filed on Jan. 23, 2024, and Taiwan application serial no. 113116076, filed on Apr. 30, 2024. The entirety of each of the above-mentioned patent applications is hereby incorporated by reference herein and made a part of this specification.

### BACKGROUND

### Technical Field

The present invention relates to a substrate structure, and more particularly to a substrate structure having improved electrical reliability.

### Related Art

Currently, to fabricate through glass vias (TGVs) with high aspect ratios (AR) in glass substrates, two glass substrates are typically joined through a resin material, and the TGVs in the two glass substrates are electrically connected through conductive paste in the resin material. That is, after the two glass substrates are joined, conductive paste exists between the two TGVs. However, after joining, the conductive paste and the metal material in the TGVs are prone to electrical discontinuity issues due to resistance variations, thereby affecting the electrical reliability of the formed substrate structure.

### SUMMARY

The present invention provides a substrate structure having improved electrical reliability.

The substrate structure of the present invention includes a first substrate and a second substrate. The first substrate includes a first dielectric substrate, at least one first conductive via extending through the first dielectric substrate, at least one first conductive pad, a first bonding layer, and a first electroless metal layer. The at least one first conductive pad and the first bonding layer are configured on the first dielectric substrate. The at least one first conductive pad is electrically connected to the at least one first conductive via. The first electroless metal layer is configured on the at least one first conductive pad and electrically connected to the at least one first conductive pad. The second substrate includes a second dielectric substrate, at least one second conductive via extending through the second dielectric substrate, at least one second conductive pad, a second bonding layer, and a second electroless metal layer. The at least one second conductive pad and the second bonding layer are configured on the second dielectric substrate. The at least one second conductive pad is electrically connected to the at least one second conductive via. The second electroless metal layer is configured on the at least one second conductive pad and electrically connected to the at least one second conductive pad. The second substrate is bonded to the first substrate, the second bonding layer is bonded to the first bonding layer to define a non-metallic contact interface, and the second electroless metal layer is bonded to the first electroless metal layer to define a metal bonding contact interface.

In an embodiment of the present invention, a first surface of the at least one first conductive pad relatively away from the first dielectric substrate is aligned with a second surface of the first bonding layer relatively away from the first dielectric substrate. A third surface of the at least one second conductive pad relatively away from the second dielectric substrate is aligned with a fourth surface of the second bonding layer relatively away from the second dielectric substrate.

In an embodiment of the present invention, a dimension of the at least one first conductive pad is larger than a dimension of the at least one first conductive via. A dimension of the at least one second conductive pad is larger than a dimension of the at least one second conductive via.

In an embodiment of the present invention, a dimension of the at least one first conductive pad is smaller than or equal to a dimension of the at least one first conductive via. A dimension of the at least one second conductive pad is smaller than or equal to a dimension of the at least one second conductive via.

In an embodiment of the present invention, a material of the at least one first conductive via and a material of the at least one second conductive via respectively include conductive paste.

In an embodiment of the present invention, the at least one first conductive via and the at least one second conductive via respectively include a seed layer and a conductive material configured on the seed layer.

In an embodiment of the present invention, a material of the first bonding layer and a material of the second bonding layer respectively include organic polymer material.

In an embodiment of the present invention, the non-metallic contact interface includes a covalent bonding contact interface or a thermoplastic adhesive contact interface.

In an embodiment of the present invention, a material of the first electroless metal layer and a material of the second electroless metal layer respectively include nano-twin copper (Nt-Cu).

In an embodiment of the present invention, the substrate structure further includes at least one build-up structure layer configured on at least one of the first substrate and the second substrate, and electrically connected to at least one of the at least one first conductive via and the at least one second conductive via.

Based on the above, in the substrate structure of the present invention, the second bonding layer is bonded to the first bonding layer to define the non-metallic contact interface, and the second electroless metal layer on the second conductive pad is bonded to the first electroless metal layer on the first conductive pad to define the metal bonding contact interface, thereby bonding the second substrate to the first substrate to form the substrate structure having dielectric vias with a high aspect ratio. Compared with the prior art, the present embodiment does not require additional resin material having conductive paste and/or adoption of the glass substrate with high thickness, and may have advantages of simple process, reduced cost, and increased production capacity. In addition, since the substrate structure of the present invention does not require additional resin material having conductive paste, the electrical continuity among the first conductive via, the first conductive pad, the first electroless metal layer, the second electroless metal layer, the second conductive pad, and the second conductive via may enable the substrate structure of the present invention to have better electrical reliability.

To make the above features and advantages of the present invention more comprehensible, embodiments are described in detail below with reference to the accompanying drawings.

### BRIEF DESCRIPTION OF THE DRAWINGS

FIG. 1A to FIG. 1I are schematic cross-sectional views of a method for fabricating a substrate structure according to an embodiment of the present invention.

FIG. 2 is a schematic cross-sectional view of a substrate structure according to an embodiment of the present invention.

FIG. 3 is a schematic cross-sectional view of a substrate structure according to another embodiment of the present invention.

FIG. 4 is a schematic cross-sectional view of a substrate structure according to another embodiment of the present invention.

### DESCRIPTION OF THE EMBODIMENTS

The embodiments of the present invention may be understood in conjunction with the drawings, and the drawings of the present invention are also considered as part of the disclosure. It should be understood that the drawings of the present invention are not drawn to scale; in fact, the dimensions of the elements may be arbitrarily enlarged or reduced to clearly illustrate the features of the present invention.

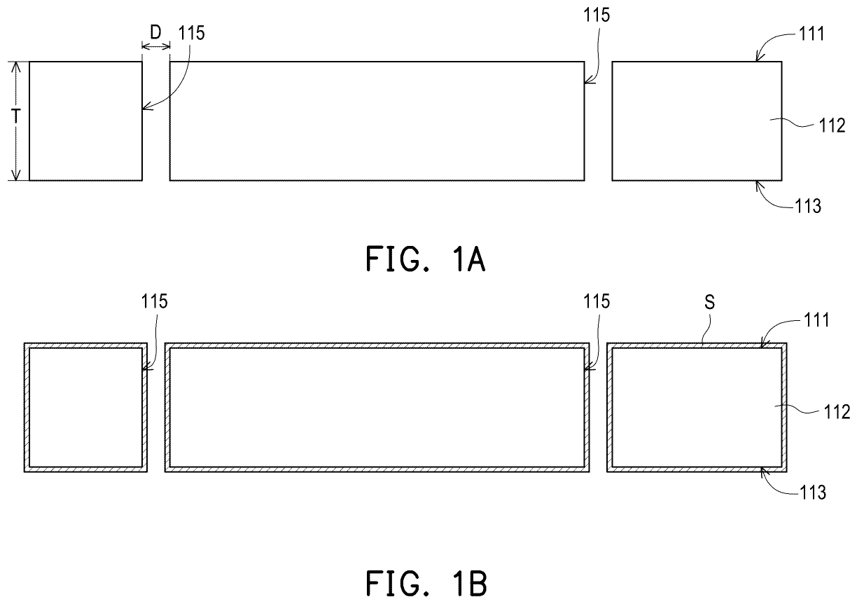

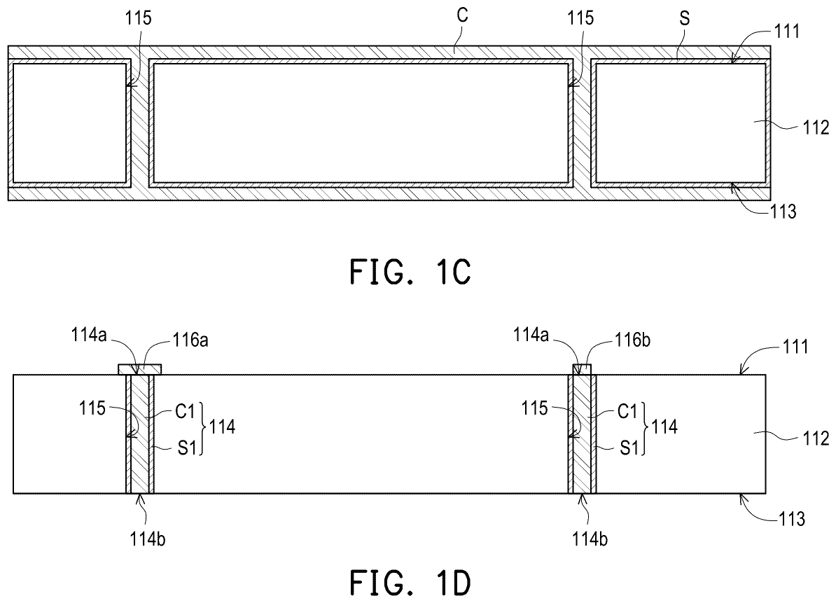

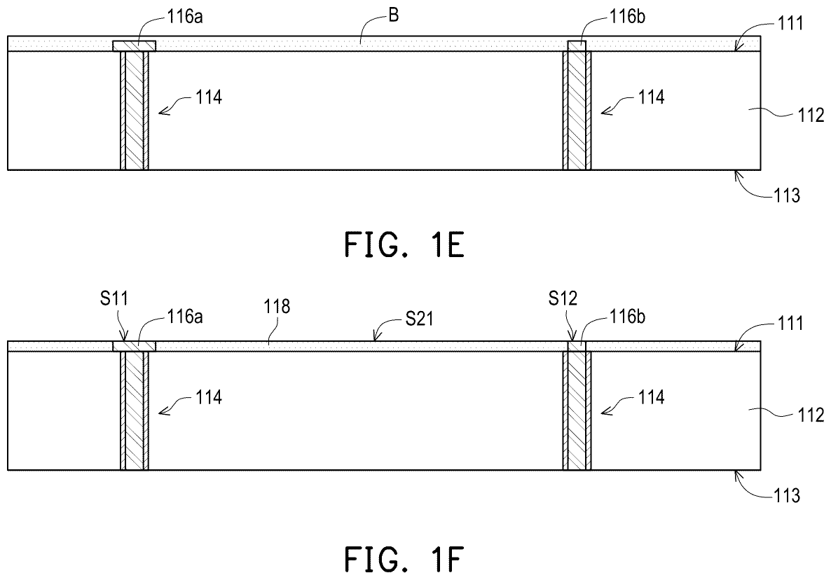

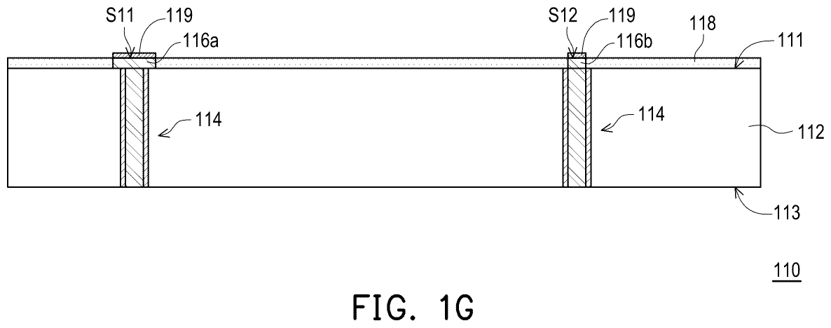

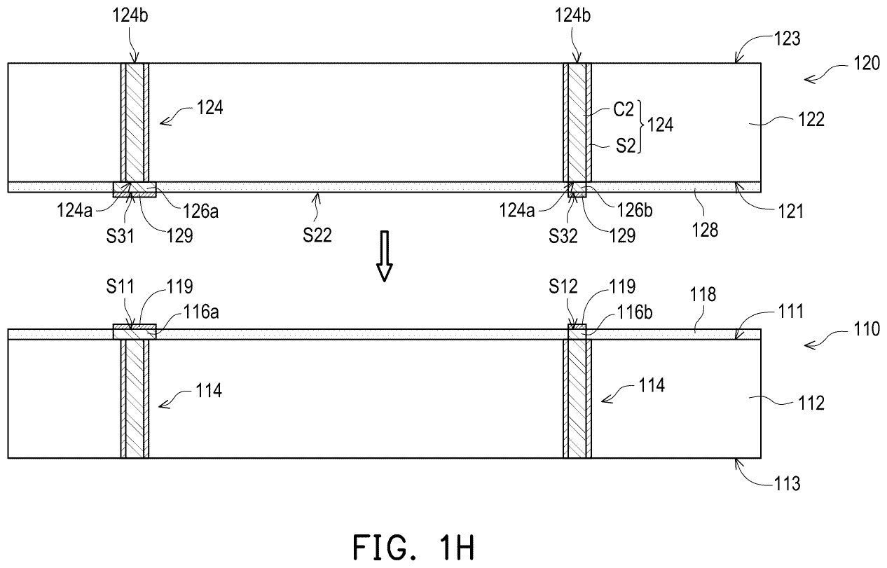

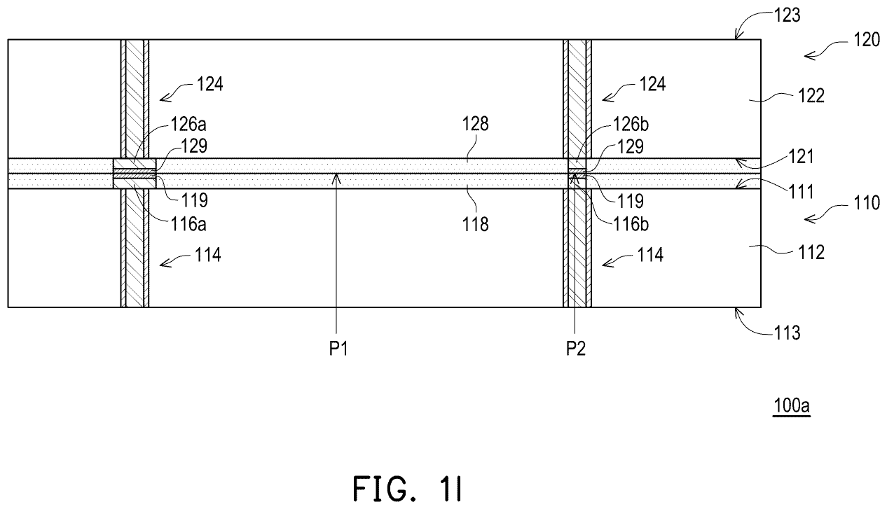

FIG. 1A to FIG. 1I are schematic cross-sectional views of a method for fabricating a substrate structure according to an embodiment of the present invention. According to the method for fabricating the substrate structure of the present embodiment, first, referring to FIG. 1A, a first dielectric substrate 112 is provided. The first dielectric substrate 112 has an upper surface 111 and a lower surface 113 opposite to each other, and at least one through hole (two through holes 115 are schematically illustrated) extending through the first dielectric substrate 112. In one embodiment, the material of the first dielectric substrate 112 is, for example, an inorganic material, wherein the inorganic material is, for example, glass, ceramic, or glass-ceramic. In one embodiment, the material of the first dielectric substrate 112 is, for example, a non-conductive composite material. In one embodiment, the thickness T of the first dielectric substrate 112 is, for example, between 100 micrometers and 400 micrometers. In one embodiment, the surface roughness of the first dielectric substrate 112, such as arithmetic average roughness (Ra), is less than 10 nanometers. In one embodiment, the through hole 115 may be a through glass via (TGV). In one embodiment, the diameter D of the through hole 115 is, for example, between 20 micrometers and 150 micrometers.

Next, referring to FIG. 1B, a seed layer S is formed on the upper surface 111 of the first dielectric substrate 112, on the lower surface 113, and on the hole walls of the through holes 115 by a dry process (for example, a sputtering process), or by a wet process (for example, an electroless plating process), or by a hybrid process (including dry and wet processes). The seed layer S may provide a good interface so that a metal layer subsequently formed thereon may be more easily adhered, thereby reducing the risk of detachment or peeling. In one embodiment, the material of the seed layer S is, for example, titanium-copper.

Next, referring to FIG. 1C, using the seed layer S as a plating seed layer, a conductive material C is plated on the seed layer S. In one embodiment, the conductive material C directly covers the seed layer S and completely fills the through holes 115, wherein the conductive material C adheres tightly to the seed layer S. In one embodiment, the material of the conductive material C is, for example, copper. In one embodiment, the conductive material C may also be formed only within the through holes 115 and on the upper surface 111 of the first dielectric substrate 112, or may be formed only within the through holes 115 and on the lower surface 113 of the first dielectric substrate 112.

Next, referring to both FIG. 1C and FIG. 1D, through, for example, an etching process, the conductive material C is patterned to remove a portion of the conductive material C located on the upper surface 111 of the first dielectric substrate 112, all of the conductive material C located on the lower surface 113 of the first dielectric substrate 112, and the seed layer S located below the conductive material layer C, thereby forming first conductive pads 116a, 116b on the upper surface 111 and completely exposing the lower surface 113 of the first dielectric substrate 112. At this time, the seed layer S1 and the conductive material C1 located within the through holes 115 define the first conductive vias 114. The first end 114a and the second end 114b, which are opposite to each other, of the first conductive vias 114 are respectively aligned with the upper surface 111 and the lower surface 113 of the first dielectric substrate 112. That is, the first conductive vias 114 extend through the first dielectric substrate 112.

Furthermore, the first conductive pads 116a, 116b are formed on the upper surface 111 of the first dielectric substrate 112 and are structurally and electrically connected to the first conductive vias 114. More specifically, the dimension of the first conductive pad 116a is larger than the dimension of the first conductive via 114, and the dimension of the first conductive pad 116b is smaller than the dimension of the first conductive via 114. In one embodiment, the orthogonal projection area of the first conductive pad 116a on the upper surface 111 of the first dielectric substrate 112 is larger than the area of the first end 114a of the first conductive via 114, that is, the first conductive pad 116a not only covers the first end 114a of the first conductive via 114, but also extends outwardly to cover a portion of the upper surface 111. In one embodiment, the orthogonal projection area of the first conductive pad 116b on the upper surface 111 of the first dielectric substrate 112 is smaller than the area of the first end 114a of the first conductive via 114, that is, the first conductive pad 116b only covers a portion of the first end 114a of the first conductive via 114. In another embodiment not shown, the dimension of the first conductive pad may be equal to the dimension of the first conductive via.

Next, referring to FIG. 1E, a bonding material layer B is formed on the upper surface 111 of the first dielectric substrate 112 by, for example, a coating method. In one embodiment, the material of the bonding material layer B is an organic polymer material, which may be, for example, a polyimide-based material or a photo-imageable based material. In one embodiment, the bonding material layer B may be pre-cured or fully cured. In one embodiment, the bonding material layer B may be a thermoplastic material.

Next, referring to both FIG. 1E and FIG. 1F, a portion of the bonding material layer B is removed by, for example, a chemical-mechanical-polishing process (CMP) to form the first bonding layer 118. In one embodiment, the first surfaces S11, S12 of the first conductive pads 116a, 116b relatively away from the first dielectric substrate 112 are aligned with the second surface S21 of the first bonding layer 118 relatively away from the first dielectric substrate 112. In one embodiment, the first surfaces S11, S12 of the first conductive pads 116a, 116b relatively away from the first dielectric substrate 112 may slightly protrude from the second surface S21 of the first bonding layer 118 relatively away from the first dielectric substrate 112.

Next, referring to FIG. 1G, a first electroless metal layer 119 is formed on the first surfaces S11, S12 of the first conductive pads 116a, 116b by an electroless plating method. That is, the first electroless metal layer 119 is only formed on the first surfaces S11, S12 of the first conductive pads 116a, 116b and is conformally configured with the first conductive pads 116a, 116b. In other words, there is a height difference between the first electroless metal layer 119 and the first bonding layer 118. In one embodiment, the material of the first electroless metal layer 119 is, for example, nano-twin copper (Nt-Cu). At this point, the fabrication of the first substrate 110 is completed.

Afterwards, referring to FIG. 1H, a second substrate 120 is provided, wherein the structure of the second substrate 120 is the same as the structure of the first substrate 110, and the fabrication method of FIG. 1A to FIG. 1G may be referred to. In brief, the second substrate 120 includes a second dielectric substrate 122, a second conductive via 124 extending through the second dielectric substrate 122, second conductive pads 126a, 126b and a second bonding layer 128 configured on the second dielectric substrate 122, and a second electroless metal layer 129 configured on the second conductive pads 126a, 126b. The second conductive via 124 includes a seed layer S2 and a conductive material C2 configured on the seed layer S2. The first end 124a and the second end 124b of the second conductive via 124 opposite to each other are respectively aligned with the upper surface 121 and the lower surface 123 of the second dielectric substrate 122 opposite to each other. The second conductive pads 126a, 126b are located on the upper surface 121 of the second dielectric substrate 122 and are electrically connected to the second conductive via 124.

In one embodiment, the dimension of the second conductive pad 126a is larger than the dimension of the second conductive via 124, and the dimension of the second conductive pad 126b is smaller than the dimension of the second conductive via 124. In one embodiment, the orthogonal projection area of the second conductive pad 126a on the upper surface 121 of the second dielectric substrate 122 is larger than the area of the first end 124a of the second conductive via 124, that is, the second conductive pad 126a not only covers the first end 124a of the second conductive via 124, but also extends outward to cover a portion of the upper surface 121. In one embodiment, the orthogonal projection area of the second conductive pad 126b on the upper surface 121 of the second dielectric substrate 122 is smaller than the area of the first end 124a of the second conductive via 124, that is, the second conductive pad 126b only covers a portion of the first end 124a of the second conductive via 124. In another embodiment not shown, the dimension of the second conductive pad may be equal to the dimension of the second conductive via. In one embodiment, the third surfaces S31, S32 of the second conductive pads 126a, 126b relatively away from the second dielectric substrate 122 are aligned with the fourth surface S22 of the second bonding layer 128 relatively away from the second dielectric substrate 122. In one embodiment, the third surfaces S31, S32 of the second conductive pads 126a, 126b relatively away from the second dielectric substrate 122 may slightly protrude from the fourth surface S22 of the second bonding layer 128 relatively away from the second dielectric substrate 122. In one embodiment, the material of the second bonding layer 128 is an organic polymer material, which may be, for example, a polyimide-based material or a photo-imageable based material. The second electroless metal layer 129 is located on the third surfaces S31, S32 of the second conductive pads 126a, 126b and is electrically connected to the second conductive pads 126a, 126b. In one embodiment, the material of the second electroless metal layer 129 is, for example, nano-twin copper.

Finally, referring to FIG. 1H and FIG. 1I, the second substrate 120 is placed above the first substrate 110 such that the second bonding layer 128 faces the first bonding layer 118, and the second electroless metal layer 129 is aligned with the first electroless metal layer 119. Subsequently, the second substrate 120 and the first substrate 110 are bonded at high temperature (such as 150° C. to 250° C.) and high pressure (such as greater than one atmosphere), wherein the second substrate 120 is bonded to the first substrate 110, the second bonding layer 128 is bonded to the first bonding layer 118 to define a non-metallic contact interface P1, and the second electroless metal layer 129 is bonded to the first electroless metal layer 119 to define a metal bonding contact interface P2. Since the first bonding layer 118 and the second bonding layer 128 adopt organic polymer material, and the first electroless metal layer 119 and the second electroless metal layer 129 adopt, for example, nano-twin copper, wherein the coefficient of thermal expansion of the organic polymer material is greater than the coefficient of thermal expansion of nano-twin copper, therefore when the second substrate 120 and the first substrate 110 are bonded, the second bonding layer 128 and the first bonding layer 118 are bonded together due to thermal expansion. In one embodiment, the non-metallic contact interface P1 may be a covalent bonding contact interface, that is, a chemical bonding contact interface formed by atoms sharing electrons. In one embodiment, the non-metallic contact interface P1 may be a thermoplastic adhesive contact interface, that is, molecules are adhered into a contact interface through intermolecular forces rather than chemical bonding forces. At this point, the fabrication of the substrate structure 100a is completed.

Structurally, referring again to FIG. 1I, the substrate structure 100a of this embodiment includes the first substrate 110 and the second substrate 120. The first substrate 110 includes the first dielectric substrate 112, the first conductive via 114 extending through the first dielectric substrate 112, the first conductive pads 116a, 116b, the first bonding layer 118, and the first electroless metal layer 119. The first conductive pads 116a, 116b and the first bonding layer 118 are configured on the first dielectric substrate 112. The first conductive pads 116a, 116b are electrically connected to the first conductive via 114. The first electroless metal layer 119 is configured on the first conductive pads 116a, 116b and is electrically connected to the first conductive pads 116a, 116b. The second substrate 120 includes the second dielectric substrate 122, the second conductive via 124 extending through the second dielectric substrate 122, the second conductive pads 126a, 126b, the second bonding layer 128, and the second electroless metal layer 129. The second conductive pads 126a, 126b and the second bonding layer 128 are configured on the second dielectric substrate 122. The second conductive pads 126a, 126b are electrically connected to the second conductive via 124. The second electroless metal layer 129 is configured on the second conductive pads 126a, 126b and is electrically connected to the second conductive pads 126a, 126b. The second substrate 120 is bonded to the first substrate 110, the second bonding layer 128 is bonded to the first bonding layer 118 to define the non-metallic contact interface P1, and the second electroless metal layer 129 is bonded to the first electroless metal layer 119 to define the metal bonding contact interface P2.

In brief, the second bonding layer 128 of this embodiment may be bonded to the first bonding layer 118 through chemical bonding or intermolecular forces to define the non-metallic contact interface P1, and the second electroless metal layer 129 on the second conductive pads 126a, 126b is bonded to the first electroless metal layer 119 on the first conductive pads 116a, 116b through metal diffusion to define the metal bonding contact interface P2, thereby bonding the second substrate 120 to the first substrate 110 to form the substrate structure 100a having dielectric vias (such as glass vias) with high aspect ratios. Compared to the prior art, this embodiment does not require additional resin material having conductive paste and/or adoption of high-thickness glass substrates, and may have advantages of simple process, reduced cost, and increased production capacity. In addition, because the substrate structure 100a of this embodiment does not require additional resin material having conductive paste, the electrical continuity among the first conductive via 114, the first conductive pads 116a, 116b, the first electroless metal layer 119, the second electroless metal layer 129, the second conductive pads 126a, 126b, and the second conductive via 124 enables the substrate structure 100a of this embodiment to have better electrical reliability.

Other embodiments will be listed below for illustration. It must be noted here that the following embodiments use the element numbers and partial content of the aforementioned embodiments, wherein the same reference numbers are used to represent the same or similar elements, and descriptions of the same technical content are omitted. For descriptions of the omitted portions, reference may be made to the aforementioned embodiments, and the following embodiments will not be repeated redundantly.

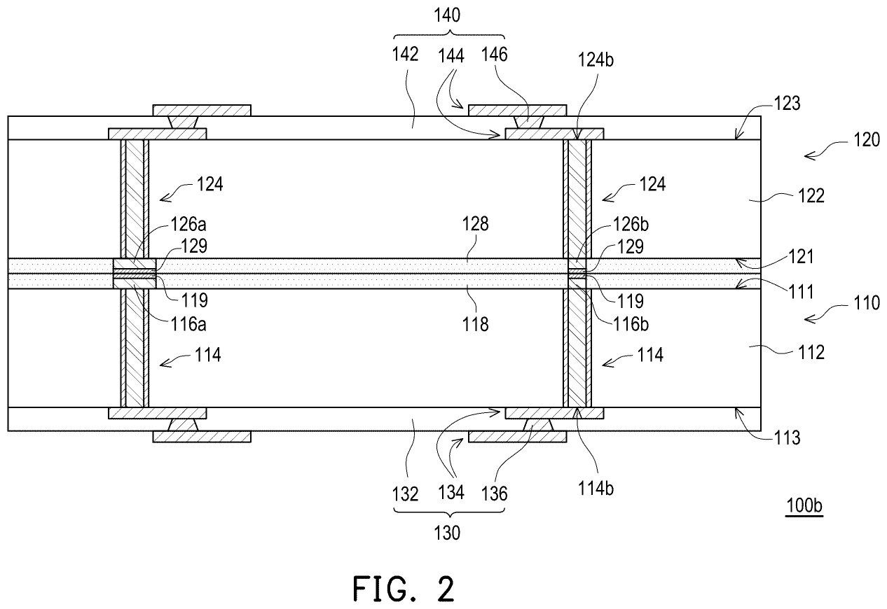

FIG. 2 is a schematic cross-sectional view of a substrate structure according to an embodiment of the present invention. Please refer to FIG. 1I and FIG. 2 simultaneously. The substrate structure 100b of this embodiment is similar to the substrate structure 100a of FIG. 1I described above, but the main difference between the two is that: in this embodiment, the substrate structure 100b further includes at least one build-up structure layer configured on at least one of the first substrate 110 and the second substrate 120, and electrically connected to at least one of the first conductive via 114 and the second conductive via 124. Furthermore, the substrate structure 100b of this embodiment includes build-up structure layers 130, 140 respectively configured on the lower surface 113 of the first substrate 110 and the lower surface 123 of the second substrate 120, wherein the first substrate 110 and the second substrate 120 are located between the build-up structure layers 130, 140. In one embodiment, the build-up structure layers 130, 140 respectively include dielectric layers 132, 142, circuit layers 134, 144, and conductive blind vias 136, 146, wherein the dielectric layers 132, 142 and the circuit layers 134, 144 are alternately stacked, and the conductive blind vias 136, 146 connect the circuit layers 134, 144. In one embodiment, the circuit layers 134, 144 of the build-up structure layers 130, 140 are electrically connected to the second end 114b of the first conductive via 114 and the second end 124b of the second conductive via 124, respectively.

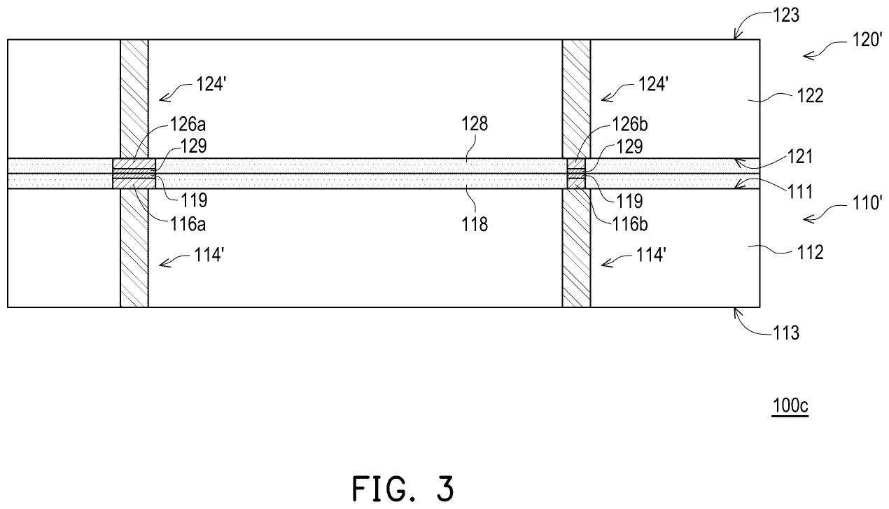

FIG. 3 is a schematic cross-sectional view of a substrate structure according to an embodiment of the present invention. Please refer to FIG. 1I and FIG. 3 simultaneously. The substrate structure 100c of this embodiment is similar to the substrate structure 100a of FIG. 1I described above, but the main difference between the two is that: in this embodiment, the material of the first conductive via 114′ of the first substrate 110′ and the material of the second conductive via 124′ of the second substrate 120′ are respectively conductive paste. In the process, the fabrication of the first conductive via 114′ and the second conductive via 124′ may be completed first, and then plating and etching processes may be performed on the first substrate 110′ and the second substrate 120′ respectively to form the first conductive pads 116a, 116b and the second conductive pads 126a, 126b.

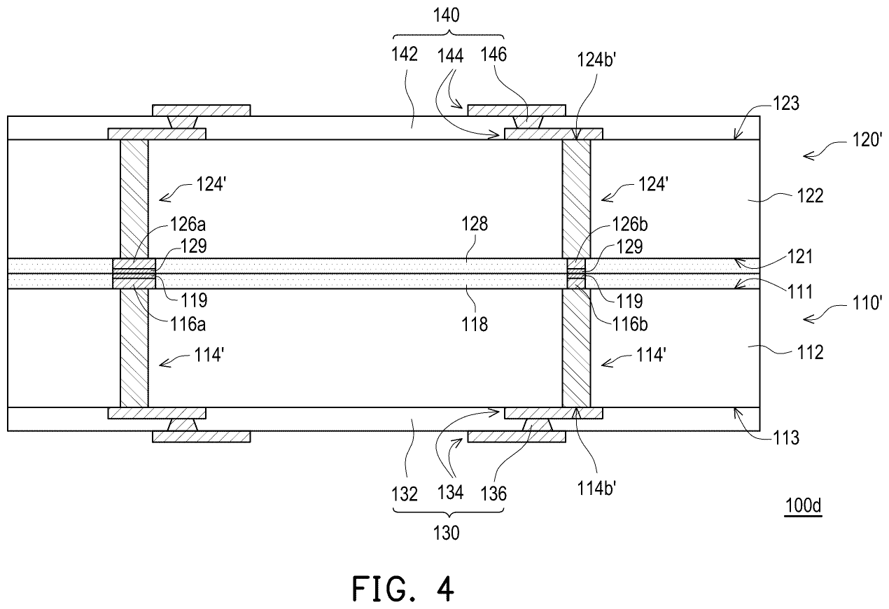

FIG. 4 is a schematic cross-sectional view of a substrate structure according to an embodiment of the present invention. Please refer to FIG. 3 and FIG. 4 simultaneously. The substrate structure 100d of this embodiment is similar to the substrate structure 100c of FIG. 3 described above, but the main difference between the two is that: in this embodiment, the substrate structure 100d includes build-up structure layers 130, 140, respectively configured on the lower surface 113 of the first substrate 110′ and the lower surface 123 of the second substrate 120′, wherein the first substrate 110′ and the second substrate 120′ are located between the build-up structure layers 130, 140. In one embodiment, the build-up structure layers 130, 140 respectively include dielectric layers 132, 142, circuit layers 134, 144, and conductive blind vias 136, 146, wherein the dielectric layers 132, 142 and the circuit layers 134, 144 are alternately stacked, and the conductive blind vias 136, 146 connect the circuit layers 134, 144. In one embodiment, the circuit layers 134, 144 of the build-up structure layers 130, 140 are electrically connected to the second end 114b′ of the first conductive via 114′ and the second end 124b′ of the second conductive via 124′, respectively.

In summary, in the substrate structure of the present invention, the second bonding layer is bonded to the first bonding layer to define the non-metallic contact interface, and the second electroless metal layer on the second conductive pad is bonded to the first electroless metal layer on the first conductive pad to define the metal bonding contact interface, thereby bonding the second substrate to the first substrate, and thus forming the substrate structure having dielectric vias with a high aspect ratio. Compared with the prior art, this embodiment does not require additional resin material having conductive paste and/or adoption of the glass substrate with high thickness, and may have the advantages of simple process, reduced cost, and increased production capacity. In addition, since the substrate structure of the present invention does not require additional resin material having conductive paste, the electrical continuity among the first conductive via, the first conductive pad, the first electroless metal layer, the second electroless metal layer, the second conductive pad, and the second conductive via may enable the substrate structure of the present invention to have better electrical reliability.

Although the present invention has been disclosed above through embodiments, they are not intended to limit the present invention. Any person having ordinary skill in the art may make some modifications and refinements without departing from the spirit and scope of the present invention. Therefore, the protection scope of the present invention shall be determined by the appended claims.

What is claimed is:

1. A substrate structure, comprising:
a first substrate, comprising a first dielectric substrate, at least one first conductive via extending through the first dielectric substrate, at least one first conductive pad, a first bonding layer, and a first electroless metal layer, wherein the at least one first conductive pad and the first bonding layer are configured on the first dielectric substrate, and the at least one first conductive pad is electrically connected to the at least one first conductive via, the first electroless metal layer is configured on the at least one first conductive pad and is electrically connected to the at least one first conductive pad; and
a second substrate, comprising a second dielectric substrate, at least one second conductive via extending through the second dielectric substrate, at least one second conductive pad, a second bonding layer, and a second electroless metal layer, wherein the at least one second conductive pad and the second bonding layer are configured on the second dielectric substrate, and the at least one second conductive pad is electrically connected to the at least one second conductive via, the second electroless metal layer is configured on the at least one second conductive pad and is electrically connected to the at least one second conductive pad;
wherein the second substrate is bonded to the first substrate, the second bonding layer is bonded to the first bonding layer to define a non-metallic contact interface, and the second electroless metal layer is bonded to the first electroless metal layer to define a metal bonding contact interface.

2. The substrate structure as claimed in claim 1, wherein a first surface of the at least one first conductive pad relatively away from the first dielectric substrate is aligned with a second surface of the first bonding layer relatively away from the first dielectric substrate, and a third surface of the at least one second conductive pad relatively away from the second dielectric substrate is aligned with a fourth surface of the second bonding layer relatively away from the second dielectric substrate.

3. The substrate structure as claimed in claim 1, wherein a dimension of the at least one first conductive pad is larger than a dimension of the at least one first conductive via, and a dimension of the at least one second conductive pad is larger than a dimension of the at least one second conductive via.

4. The substrate structure as claimed in claim 1, wherein a dimension of the at least one first conductive pad is smaller than or equal to a dimension of the at least one first conductive via, and a dimension of the at least one second conductive pad is smaller than or equal to a dimension of the at least one second conductive via.

5. The substrate structure as claimed in claim 1, wherein a material of the at least one first conductive via and a material of the at least one second conductive via respectively comprise conductive paste.

6. The substrate structure as claimed in claim 1, wherein the at least one first conductive via and the at least one second conductive via respectively comprise a seed layer and a conductive material configured on the seed layer.

7. The substrate structure as claimed in claim 1, wherein a material of the first bonding layer and a material of the second bonding layer respectively comprise organic polymer material.

8. The substrate structure as claimed in claim 1, wherein the non-metallic contact interface comprises a covalent bonding contact interface or a thermoplastic adhesive contact interface.

9. The substrate structure as claimed in claim 1, wherein a material of the first electroless metal layer and a material of the second electroless metal layer respectively comprise nano-twin copper.

10. The substrate structure as claimed in claim 1, further comprising:
at least one build-up structure layer configured on at least one of the first substrate and the second substrate, and electrically connected to at least one of the at least one first conductive via and the at least one second conductive via.
